(19) United States
(12) Patent Application Publication
(10) Pub. No.: US 2005/0150537 A1
(43) Pub. Date: Jul. 14, 2005

(54) Thermoelectric devices

(75) Inventor: Uttam Ghoshal, Austin, TX (US)

Correspondence Address: ZAGORIN O'BRIEN GRAHAM LLP, 7600B N. CAPITAL OF TEXAS HWY., SUITE 350, AUSTIN, TX, 78731, US

(73) Assignee: NANOCOOLERS INC., AUSTIN, TX (US)

(21) Appl. No.: 10/756,603

(22) Filed: Jan. 13, 2004

(51) Int. Cl. H01L 35/30

(52) U.S. Cl. 136/205

(57) ABSTRACT

A thermoelectric device with an improved figure-of-merit achieved by lowering the thermal conductivity of the thermoelectric device without significantly reducing electrical conductivity. The reduction in value of thermal conductivity is achieved by reducing the phonon thermal conductivity λₚ without significantly affecting the electron thermal conductivity λₑ. The reduction in phonon thermal conductivity λₚ is accomplished in two steps: First the phonon conduction is decoupled and separated from the electron conduction by the use of an ultra-thin film semiconductor thermoelement. And second, the phonon conduction is selectively attenuated by the use of phonon-blocking structures without affecting the electron conduction. Methods for fabrication of the thermoelectric devices are also provided.

### BACKGROUND

The present invention generally relates to the field of thermoelectric devices. In particular, the invention relates to a novel thermoelectric device structure with an improved thermoelectric figure-of-merit.

Electronic devices such as microprocessors, laser diodes etc. generate a lot of heat during operation. If the generated heat is not dissipated properly from such small devices, temperature buildup may occur in these devices. The buildup of temperature can adversely affect the performance of these devices. Thus, it is important to remove the generated heat in order to avoid thermally induced failure and maintain the normal operating temperatures of these devices.

Modern semiconductor manufacturing processes allow for very high circuit densities, leading to more dissipation of heat, which requires rigorous cooling methods. Accordingly, the conventional cooling techniques may not be suitable.

Conventional cooling systems for small devices are typically based on passive cooling methods and active cooling methods. The passive cooling methods include heat sinks and heat pipes. Such passive cooling methods provide limited cooling capacity due to spatial limitations. Active cooling methods include use of devices such as mechanical vapor compression refrigerators and thermoelectric coolers. The vapor compression based cooling systems generally require significant hardware such as a compressor, a condenser and an evaporator. Because of the high volume, moving mechanical parts, poor reliability and associated cost of this hardware, the use of such vapor compression based systems might not be suitable for cooling small electronic devices.

Thermoelectric cooling, for example using a Peltier device, provides a suitable cooling approach for cooling of small electronic devices. Thermoelectric cooling devices are based on the Peltier effect. Typically, a thermoelectric cooling device is a semiconductor with two metal electrodes. When a voltage is applied across these electrodes, heat is absorbed at one electrode producing a cooling effect, while heat is generated at the other electrode producing a heating effect. The cooling effect of these thermoelectric peltier devices can be utilized for providing solid state cooling of small electronic devices.

Some typical applications of the thermoelectric cooling devices are in the field of small-scale refrigeration. Small-scale refrigeration is required in mainframe computers, thermal management of hot chips, RF communication circuits, magnetic read/write heads, optical and laser devices, and automobile refrigeration systems.

Thermoelectric devices provide many advantages over the conventional vapor compression based cooling systems. Firstly, the thermoelectric devices have no moving parts. The lack of moving parts makes the thermoelectric cooling devices much more reliable and easy to maintain than the conventional cooling systems. Secondly, thermoelectric devices may be manufactured in small sizes making them attractive for small-scale applications. Thirdly, the absence of refrigerants in thermoelectric devices carries the obvious environmental and safety benefits. Fourth, the thermoelectric coolers may be operated in vacuum and/or weightless environments and can be oriented in different directions without effecting performance.

However, the wide spread use of thermoelectric devices has been thwarted by some limitations. The main limitation of the thermoelectric devices is the low efficiency of these devices as compared to the conventional cooling systems. The efficiency of a thermoelectric device is known to depend on material properties through a figure-of-merit (ZT):
ZT=S²Tσ/λ
where, S is the Seebeck coefficient (which is a property of a material),
T is the average temperature of the thermoelectric material,
σ is the electrical conductivity of the thermoelectric material and
λ is the thermal conductivity of the thermoelectric material

Most present day thermoelectric devices have a typical thermoelectric figure-of-merit less than 1. In order to make the thermoelectric devices as efficient as the conventional vapor compression refrigerators, the figure of merit for thermoelectric devices should be around 3.

As is evident from the above equation, a material having high electrical conductivity and low thermal conductivity will have a high figure-of-merit. This requires reduction in thermal conductivity without a significant reduction in electrical conductivity. Various approaches have been proposed to increase the figure-of-merit of the thermoelectric devices that decrease the thermal conductivity of the material while retaining high electrical conductivity.

In one of the approaches, superlattices having reduced thermal conductivity are grown on lattice-matched substrates. (A superlattice is a periodic structure generally consisting of several to hundreds of alternating thin film layers of semiconductor material where each layer is typically between 10 and 500 Angstroms thick.) Superlattices of materials such as Bi₂Te₃ and Sb₂Te₃ are grown on GaAs and BaF₂ wafers in such a way as to disrupt the thermal transport while enhancing the electronic transport in the direction perpendicular to the superlattice interfaces.

However, the superlattice approach faces the following limitations. These superlattices are grown on a semiconductor wafers and then need to be transferred to a metal surface. This is difficult to achieve and thus makes the process complex. Moreover, there have been no measurements on superlattice-based structures reported to date that demonstrate larger temperature differentials or better efficiencies.

In another approach, the thermal conductivity is reduced using quantum dots and nanowires. A quantum dot is a structure where charge carriers are confined in all three spatial dimensions. Similarly, a nanowire is an ultrafine tube of a semiconductor material. Quantum confinement of carriers in reduced dimensional structures results in larger Seebeck coefficients and hence a better thermoelectric figure of merit.

Yet another approach uses structured cold points for increasing the figure-of-merit of the thermoelectric devices. A cold point is a sharp point contact between the hot electrode and the cold electrode of a thermoelectric device. The cold points have a high ratio of electrical conductivity to thermal conductivity at the contact. This feature of the cold points is used to improve the figure-of-merit of the thermoelectric device. Figures-of-merit in the range of 1.3 to 1.6 can be achieved using these thermoelectric devices. One such device is disclosed in U.S. Pat. No. 6,467,275 Titled “Cold Point Design For Efficient Thermoelectric Coolers”. The patent discloses a thermoelectric device with a cold electrode plate and a hot electrode plate. The contact between the electrodes is achieved by using a plurality of tips of the cold points on the cold electrode and the planar surface of the hot electrode.

Similar cold point thermoelectric devices are disclosed in U.S. patent application Ser. No. 20020092557 titled “Enhanced Interface Thermoelectric Coolers With All-Metal Tips” and U.S. Pat. No. 6,384,312 Titled “Thermoelectric Coolers With Advanced Structured Coolers”. These patents describe structured cold point thermoelectric devices with an enhanced figure-of-merit.

The approach of using structured cold points suffers from various manufacturing limitations. The manufacturing process of the cold points requires precise lithographic and mechanical alignments. The tolerances of the manufacturing process for these alignments often result in degraded performance. It is difficult to maintain uniformity in radii and heights of the cold points. These factors make it practically difficult to achieve nanometer level planarity resulting in point intrusions or absence of contact. These current crowding effects that increase the current flowing through point intrusions and decrease the current in points making poor contact.

Secondly, the structured cold point devices achieve only localized cooling in a small area near each cold point. Hence, the actual area of cooling (i.e. the area around the cold points between the cold electrode and the hot electrode) is small compared to the total area to be cooled in the device. The small cooling areas result in large thermal parasitics and poor efficiency.

Hence, there is a need for a system that achieves high figure-of-merit for thermoelectric cooling devices. There is also a need for a thermoelectric cooler that achieves lower cooling temperatures than the current thermoelectric devices.

### SUMMARY

An object of the present invention is to provide a thermoelectric device with an improved figure-of-merit.

Another object of the present invention is to provide a thermoelectric device with an ultra-thin thermoelement.

Yet another object of the present invention is to provide a novel method of fabrication of a thermoelectric device.

To attain the abovementioned objectives, the invention provides a thermoelectric device comprising a solid metal electrode, a thermoelement thermally coupled to the solid metal electrode and a phonon conduction impeding medium. The phonon conduction impeding medium is coupled with the thermoelement. The phonon conduction impeding medium is also thermally insulated from the solid metal electrode. Further, a second solid metal electrode is thermally coupled to the phonon conduction impeding medium. The thermoelectric device also comprises a dielectric material for maintaining spacing between the first solid metal electrode and the second solid metal electrode. In different embodiments, multiple thermoelectric devices are connected electrically in series and thermally in parallel. The thermoelectric device can be used both as a thermoelectric cooler and a thermoelectric power generator.

### BRIEF DESCRIPTION OF THE DRAWINGS

The preferred embodiments of the invention will hereinafter be described in conjunction with the appended drawings provided to illustrate and not to limit the invention, wherein like designations denote like elements, and in which:

FIG. 1 shows a cross-section of a basic non-equilibrium asymmetric thermoelectric (NEAT) device structure in accordance with an embodiment of the present invention;

FIG. 2 shows the variation of electron and phonon temperatures within the basic NEAT device structure;

FIG. 3 shows variation of electron temperature and phonon temperature in a thermoelement;

FIG. 4 shows various phonon conduction impeding mediums in accordance with different embodiments of the present invention;

FIG. 5 shows a NEAT device having two metal plates in accordance with another embodiment of the present invention;

FIG. 6a shows a nonequilibrium symmetric thermoelectric (NEST) device in accordance with another embodiment of the present invention;

FIG. 6b shows a nonequilibrium symmetric thermoelectric (NEST) device in accordance with yet another embodiment of the present invention;

FIG. 6c shows multiple NEST devices cascaded in series;

FIG. 7a illustrates a cascaded NEAT device formed by merging NEAT devices together in series with alternate n-type and p-type thermoelements arranged on opposite side of liquid metal electrodes;

FIG. 7b shows an enlarged cross section view of a single NEAT device from the cascaded NEAT device described in conjunction with FIG. 7a;

FIG. 8 shows a cascaded NEAT device formed by merging NEAT devices together in series with alternate n-type and p-type thermoelements arranged on the same side of liquid metal electrodes; and

FIGS. 9a-9n shows the process for fabricating thermoelectric devices in accordance with various embodiments of the present invention.

### DESCRIPTION OF PREFERRED EMBODIMENTS

Before describing the present invention in greater detail, it is helpful to provide definitions of common terms utilized.

Figure of merit: The efficiency of a thermoelectric device is known to depend on material properties through a figure-of-merit ZT=S² Tσ/λ, where S is the Seebeck coefficient, σ and λ are the electrical and thermal conductivities respectively, and T is the ambient temperature. Thus a good thermoelectric material should have a high power factor (S²σ) and a low thermal conductivity.

Phonon: A phonon is a vibrational wave in a solid, and it can be viewed as a particle having energy and a wave length. Acoustic phonons carry heat and sound through a solid. They move at the speed of sound in the solid.

Phonon Glass Electron Crystal (PGEC): According to the Phonon Glass Electron Crystal (PGEC) concept, an ideal thermoelectric material should possess the (good) electronic transport properties of a crystal and resist the passage of heat as well as glass does. The PGEC concept defines the limiting characteristics of a superior thermoelectric material.

Thermalization length: When a material is heated, the electrons start moving to conduct the thermal energy. In the process, the electrons collide with phonons and share their energy with the phonons. As a result, the temperature of phonons starts increasing until a thermal equilibrium is attained between the electrons and the phonons. The distance traveled by electrons after which thermal equilibrium takes place is called thermalization length.

Phonon conduction impeding medium: Most liquids, including liquid metals, lack ionic order and crystal structure resulting in negligible phonon conduction. In addition, certain metallic solids such as Indium, Lead, Lead-Indium, and Thallium and solid-solid interfaces with Cs doping, and liquid metal-solid interfaces have poor phonon conductivity. Such materials have been referred to as phonon conduction impeding medium in the present invention.

The present invention provides a thermoelectric device with improved figure-of-merit. A high figure of merit is achieved by lowering the thermal conductivity of the thermoelectric device without significant reduction in electrical conductivity.

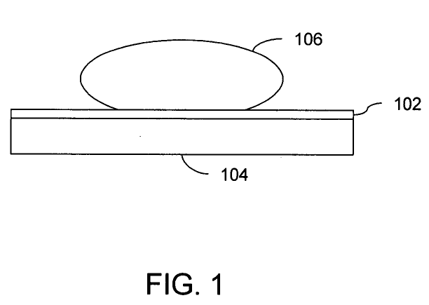

Referring to FIG. 1, a cross-section of a non-equilibrium asymmetric thermoelectric (NEAT) device structure in accordance with an embodiment of the present invention is shown.

The NEAT device structure consists of a thermoelement 102 thermally coupled with a metal plate that acts as a solid metal electrode 104. Thermoelement 102 is an ultra-thin thermoelectric semiconductor film. Solid metal electrode 104 provides structural and mechanical stability to the ultra-thin film 102. A liquid metal electrode 106 is electrically as well as thermally coupled with thermoelement 102. Liquid metal electrode 106 is a micron-sized liquid metal droplet. The micron size liquid metal droplet is deposited over thermoelement 102 such that it does not wet thermoelement 102. It should be apparent to one skilled in the art that the liquid metal droplet is an example of a phonon conduction impeding medium and is used in accordance with one embodiment of the present invention. Any other phonon conduction impeding medium may also be used to practice the invention.

The electrical connection between liquid metal electrode 106 and thermoelement 102 is established mainly by electron tunneling across a sub-nanometer tunneling gap at the interface between liquid metal electrode 106 and thermoelement 102. This tunneling gap is formed due to non-adherence of molecules of liquid metal electrode 106 with the molecules of thermoelement 102. The electrical conduction properties of the tunneling gap are dependent on the atomic gaps, which in turn are dependent on the wetting and surface tension properties of the liquid metal. A small tunneling gap results in an almost ideal electrical conduction.

The thermoelectric semiconductor utilized in the construction of thermoelement 102 has a high power factor (S²σ) and thickness less than its characteristic thermalization length. For ambient applications, exemplary thermoelectric semiconductor materials include p-type Bi_{0.5}Sb_{1.5}Te₃ and n-type Bi₂Te_{3.2} and superlattices of constituent compounds such as Bi₂Te₃/Sb₂Te₃ superlattices. At higher temperatures, lead chacogenides such as PbTe or skutteridites such as CoSb₃ and traditional alloy semiconductors SiGe may be used. At low temperatures, BiSb alloys may be an optimal choice. Solid metal electrode 104 may be a Nickel-plated copper wafer or aluminum with TiW/Pt barriers. Thermoelement 102 is deposited onto solid metal electrode 104 using techniques such as sputtering, electrodeposition, molecular beam epitaxy (MBE) or metal organic chemical vapor deposition (MOVCD).

Representative materials that may be used to form the phonon conduction impeding medium include Gallium (Ga), Indium (In), Lead (Pb), Lead-Indium, Lead-Indium-Tin, Gallium-Indium, Gallium-Indium-Tin, Ga-In with Cesium doping at the surface. Preferred compositions comprise 65 to 75% by mass Gallium and 20 to 25% Indium. Materials such as Tin, Copper, Zinc and Bismuth may also be present in small percentages. One such preferred composition comprises 66% Gallium, 20% Indium, 11% Tin, 1% Copper, 1% Zinc and 1% Bismuth. In other embodiments, materials like Mercury, Bismuth Tin alloy (58% Bismuth, 42% Tin by mass), Bismuth Lead alloy (55% Bismuth, 45% Lead) etc. may be used.

The solid metal electrode may be replaced by any highly-doped semiconductor such as antimony or phosporus doped silicon or germanium with carrier concentrations greater than 10²⁰ cm⁻³

Hereinafter, the principle behind working of the NEAT device structure is explained in detail.

In accordance with the present invention, the figure of merit of the NEAT device structure is increased by decreasing its thermal conductivity without causing a significant reduction in electrical conductivity.

The thermal conductivity of the thermoelectric device is made up of two components. One is the thermal conductivity due to electrons (referred to as electron thermal conductivity λₑ hereinafter) and other is thermal conductivity due to phonons, which forms the major component (referred to as phonon thermal conductivity λₚ hereinafter). Thus,
λ=λₑ+λₚ

Thus, the value of λ can be reduced by reduction in value of either λₑ or λₚ. However, any reduction in λₑ would require a reduction in electrical conductivity σ, thereby leading to an overall reduction in the value of figure of merit, ZT (as can be seen from the mathematical expression for ZT). Therefore, to reduce the value of λ without affecting the value of σ requires a reduction in value of λₚ without significantly affecting λₑ.

The use of liquid metal droplet and ultra-thin thermoelectric film in the NEAT device structure results in a minimal value of λₚ (which is the major component of λ) thereby reducing the value of λ.

The reduction of phonon thermal conductivity λₚ is accomplished in two steps: First the phonon conduction is decoupled and separated from the electron conduction by the use of an ultra-thin film semiconductor thermoelement. And second, the phonon conduction is selectively attenuated by the use of phonon-blocking structure without affecting the electron conduction.

Consider a thermoelectric device structure in accordance with the embodiment illustrated in FIG. 1 wherein the thickness of the thermoelement is t. An electrical potential is applied across the thermoelement such that the electric current flows from solid metal electrode 104 to liquid metal electrode 106. Hence, the electrons will flow in the opposite direction. Once injected into the thermoelement 102 from the liquid metal electrode, the electrons are not in a thermal equilibrium with the phonons in the thermoelement for a finite distance Λ from the surface of contact of the cold electrode and the thermoelement. This finite distance Λ is known as thermalization length. The thickness t of the thermoelement used in the present invention is smaller than the distance Λ. Hence the electrons and phonons are not in a thermal equilibrium in the thermoelement and do not affect each other in the energy transport.

Once the phonon transport process and the electron transport process are separated, the difference in the thermal conduction mechanisms in liquid metals and solid metals is exploited to create the phonon-blocking or phonon-attenuating structure in the NEAT device structure, as explained below.

Thermal conduction in metals (liquid as well as solid) is due to the transport of electrons and phonons. A unique characteristic of liquid metals (and liquid metal alloys) vis-à-vis solid metals is the lack of ionic order and crystal structure. This results in low acoustic velocities and negligible phonon thermal conductivity λₚ in the liquid metals as compared to phonon thermal conductivity of solid metals. (The phonon thermal conductivity of the liquid metals is less than the phonon conductivity of typical solid-phase glasses or polymers with thermal conductivity values less than 0.1 W/m.K). As a result, the thermal conductivity in liquid metals is predominantly due to electrons. Therefore, when liquid metal is used as one of the electrodes, the electron phonon coupling is minimal in the liquid metal electrode of the NEAT device structure.

There are interface thermal resistances such as Kapitza thermal boundary resistances between the liquid metal and the thermoelement that arise due to mismatch of the acoustic velocities in the two mediums.

The liquid metal structure can be replaced by other phonon conduction impeding mediums such as interfaces created by Cesium doping or using solid metals such as Indium, Lead and Thallium that have very low acoustic velocities. The net effect is that phonon thermal conductivity between the electrodes of the thermoelectric cooler is significantly reduced.

The electronic conduction is separated from the phonon-conduction and is not impeded because the liquid metals have high electronic conductivities and the electrons can tunnel through the interface barriers with minimal resistance.

Due to the reduction of phonon thermal conductivity λₚ to negligible amounts (because of use of liquid metal and thin thermoelectric thermoelement), the thermal conductivity in the NEAT device structure is predominantly due to electron thermal conductivity λₑ. Thus λ→λₑ. Hence there is a reduction in value of thermal conductivity λ, which in turn leads to improved figure of merit ZT.

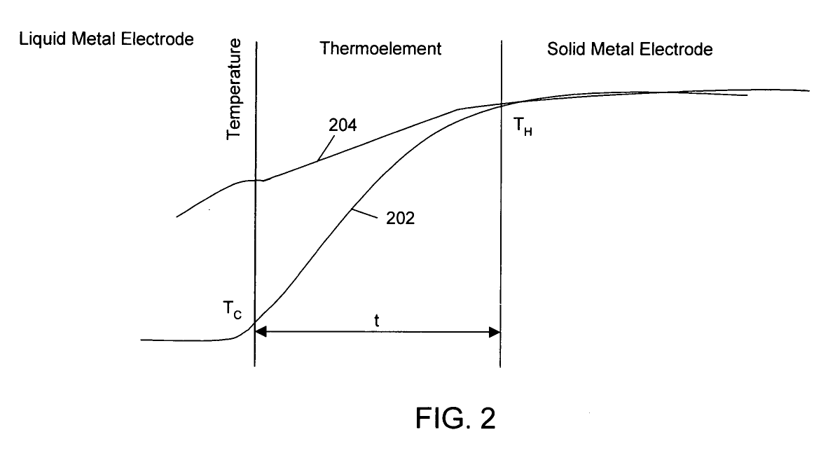

FIG. 2 shows the variation of electron and phonon temperatures within the NEAT structure. The temperature of liquid metal electrode 106 is T_{C} while the temperature of solid metal electrode 104 is T_{H}. As the thermal conduction in metals is predominantly because of the electrons, the temperature of electrons in liquid metal electrode 106 is T_{C}, while the temperature of electrons in solid metal electrode 104 is T_{H}. The variation of temperature 202 of electrons in thermoelement 102 is nonlinear and is governed by heat conduction equations described later.

The temperature of phonons in solid metal electrode 104 is equal to T_{H} (because of the electron-phonon coupling within the solid). However, in the liquid metal electrode, there is no phonon structure due to lack of ionic order. The temperature of the ion cores in the liquid metal electrode is same as that of the electrons (T_{c}). The temperature of phonons in the thermoelectric layer at the liquid metal interface is not equal to the liquid metal temperature because of the large thermal impedance of the phonons at the interface. The temperature of the phonons in thermoelement 102 varies between the temperature of solid metal plate T_{H} and the temperature of phonons in cold electrode 106. This variation of temperature 204 is shown in FIG. 2. As is evident from the figure, the electron and the phonon temperatures in thermoelement 102 are not in equilibrium.

One-dimensional coupled equations that describe the heat transfer for the electron-phonon system within the thermoelement may be derived using the Kelvin relationship, the charge conservation equation and the energy conservation equation. The coupled equations for heat transfer may be represented as:
−∇·(λₑ∇Tₑ)−|\overline{J}|²/σ+P(Tₑ−Tₚ)=0
−∇·(λₚ∇Tₚ)−P(Tₑ−Tₚ)=0
where,
Tₑ is the temperature of the electrons,
Tₚ is the temperature of the phonons,
λₑ is the electrical conductivity of the thermoelement,
J is the local current density,
σ is the electrical conductivity of the thermoelement,
λₚ is the lattice thermal conductivity of the thermoelement, and
P is a parameter that represents the intensity of the electron-phonon interaction.

More information on the parameter P representing the intensity of the electron-phonon interaction may be obtained from “Semiconductors” (31, 265 (1997)) by V. Zakordonets and G. Loginov. Additional information may be obtained from a publication titled “Boundary Effects in Thin film Thermoelectrics” of M. Bartkowiak and G. Mahan from Materials Research Society Symposium Proceedings, Vol. 545, 265 (1999). The parameter P may be given for three-dimensional isotropic conduction as:
P=(3Ξ²m*²k_{B}nk_{F})/(πρ³)
where,
Ξ is the deformation interaction,
m* is the effective electron mass,
k_{B} is the Boltzmann's constant
n is the electron density,
k_{F} is the Fermi wavevector,
ρ is the density of the thermoelement, and
is the reduced Planck's constant.
   More information on this may be obtained from “Electrons and Phonons in Semiconductor Multi-layers”, (Cambridge University Press, 1997, Chapter 11.7) by B. K. Ridley.

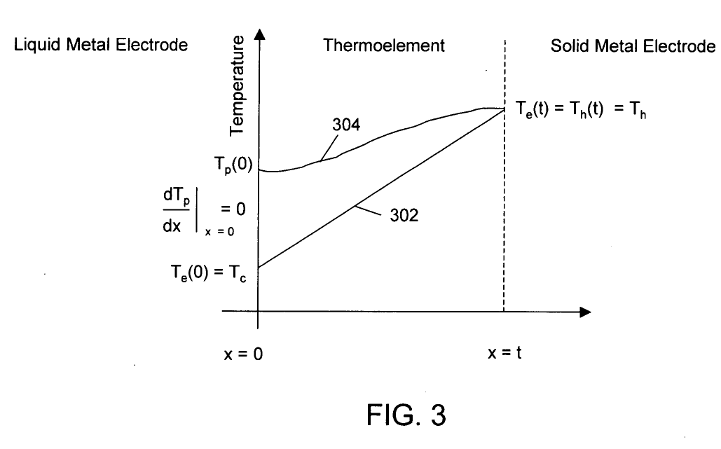

These one-dimensional coupled equations are solved subject the boundary conditions as illustrated in conjunction with FIG. 3. The figure shows variation of electron temperature 302 and phonon temperature 304 in thermoelement 102. The injected electrons in the thermoelement at the boundary x=0 have temperature equal to the temperature of the liquid metal electrode. Hence,
Tₑ(0)=T_{C}

Similarly, the temperature of electrons at the other boundary of the thermoelement is equal to the temperature of the solid metal electrode 104. The phonons are also at the same temperature as that of the solid metal electrode. This may be represented as:
Tₑ(t)=Tₚ(t)=T_{H}

Also, a zero gradient for the phonon temperature across the boundary of the liquid metal electrode and the thermoelement is assumed. This boundary condition represents the desired zero phonon conduction in the liquid metal electrode. This may be represented as:

$$\frac{ⅆ {T}_{p}}{ⅆ x} {\vert}_{x = 0} = 0$$

All the above boundary conditions are illustrated in FIG. 3.

The one-dimensional coupled equations are solved to determine heat flux q₀ as a function of the temperatures at the surfaces of the thermoelement.

$${q}_{0} = - \frac{{\vert \overline{J} \vert}^{2} t ξ}{2 σ} - {λ}_{eff} \frac{( {T}_{H} - {T}_{C} )}{t}$$

where,
ξ is the factor for reduction in Joule heat backflow, and
λ_{eff} is the effective electrical conductivity of the thermoelement.

The net cooling flux J_{q} at the cold liquid metal electrode including the Seebeck cooling effect is given by:
J_{q}=ST_{c}|J|+q₀

The effective thermal conductivity for the thermoelement 102 is represented by:

$${λ}_{eff} = \frac{{λ}_{e} ( {λ}_{e} + {λ}_{p} )}{{λ}_{e} + {λ}_{p} [ \frac{tanh ( t / Λ )}{( t / Λ )} ]}$$

It may be seen from the above equation that as t/Λ→0, λ→λₑ, for all the devices that have small thickness t, the thermal conductivity is essentially reduced to the electronic thermal conductivity. The characteristic thermalization length Λ is about 500 nanometers for Bi_{0.5}Sb_{1.5}Te₃ and Bi₂Te_{2.8}Se_{0.2} chalcogenides. The NEAT devices with film thickness of t˜100 nanometers thus have t/Λ of around 0.2. Hence, the thermal conductivity for the thermoelement is equal to the electronic thermal conductivity.

Hence, the figure-of-merit for the NEAT structure is:
ZT=S²Tσ/λₑ

The electronic thermal conductivity is related to the electrical conductivity by the Wiedeman-Franz law by the relation λₑ=L₀σT. Thus
ZT=S²/L₀

Where L₀ is the Lorenz number for the thermoelement. For pure metals, L₀=(π²/3)(k/e)².
\sqrt{L₀}˜125 microvolt/Kelvin for Bi_{0.5}Sb_{1.5}Te₃.

Hence, the thermoelement operates in the classical phonon-glass-electron-crystal (PGEC) limit at the limiting value for the figure-of-merit.

The first term

$$\frac{{\vert \overline{J} \vert}^{2} t ξ}{2 σ}$$

in the formula for q₀ depicts the backflow of Joule heat to the cold electrode. In conventional devices, half of the Joule heat developed in the thermoelement flows back to the cold electrode. But, in the device in accordance with the present invention, this backflow is reduced by a factor of ξ. The factor for reduction in Joule heat backflow ξ is given by:

$$ξ = \frac{{λ}_{e} + {λ}_{p} [ \frac{1 - sec h ( t / Λ )}{{( t / Λ )}^{2}} ]}{{λ}_{e} + {λ}_{p} [ \frac{tanh ( t / Λ )}{( t / Λ )} ]}$$

The reduction of backflow of Joule heat allows for higher efficiency operation at larger temperature differentials. Also, the minimum cold end temperature for a NEAT device may be derived to be:

$${T}_{c min} = {T}_{h} / \sqrt{1 + \frac{{S}^{2} σ}{ξ λ}} \leq {T}_{h} / \sqrt{1 + \frac{{S}^{2}}{{L}_{0}}}$$

The maximum coefficient of performance (COP)η i.e. the ratio of the cooling power at the cold electrode to the total electrical power consumed by the cooler is given by the relation:

$$η = ( \frac{\sqrt{1 + {S}^{2} / {L}_{0}} - 1}{\sqrt{1 + {S}^{2} / {L}_{0}} + 1} ) \frac{{T}_{C}}{{T}_{H} - {T}_{C}}$$

The thermodynamic efficiency ε is the ratio of the COP of the NEAT device to that of an ideal Carnot refrigerator operating between the same temperatures (T_{H} and T_{C}),

$$ɛ = ( \frac{\sqrt{1 + {S}^{2} / {L}_{0}} - 1}{\sqrt{1 + {S}^{2} / {L}_{0}} + 1} )$$

In the case of NEAT devices based on Bi_{0.5}Sb_{1.5}Te₃ or Bi₂Te₃ materials, S˜220 microVolt/Kelvin and hence ε˜0.3. It may be seen that the thermodynamic efficiency of a NEAT device in accordance with the present invention is competitive with mechanical vapor compression refrigerators. This completes the description of the NEAT structure.

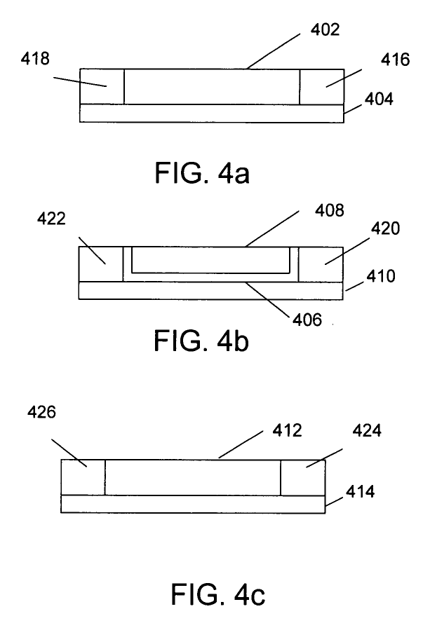

FIG. 4 shows the various phonon conduction impeding mediums that can be used in various embodiments of the invention. FIG. 4a shows the use of liquid metal as a phonon conduction impeding medium in accordance with the preferred embodiment of the invention. As shown liquid metal 402 is placed on the thermoelement interface 404. A combination of liquid metal and cesium vapor doping can also be used to further reduce the value of phonon thermal conductivity. As shown in FIG. 4b cesium vapor doping 406 is done at the interface of liquid metal 408 and thermoelement 410.

In addition to liquid metals, certain metallic solids such as Indium, Lead, and Thallium also have poor phonon conductivity and can be used for phonon blocking. FIG. 4c shows the use of solid Indium as the phonon conduction impeding medium in accordance with an alternative embodiment of the invention. As shown solid Indium 412 is sputtered on thermoelement 414.

Dielectric dams 416, 418, 420, 422, 424, and 426 contain the various phonon conduction impeding mediums and are also utilized to support metal links that connect the electrodes 402, 408, and 412.

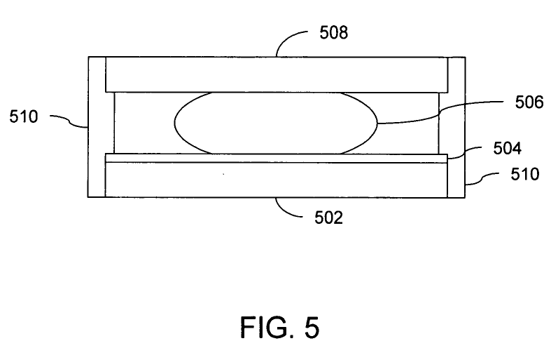

Referring primarily to FIG. 5, a macroscopic NEAT thermoelectric device is illustrated in accordance with an embodiment of the present invention. FIG. 5 shows a NEAT device having two metal plates. A first metal plate 502 is coupled to a thermoelement 504. The thermoelement is a thin layer (10-100 nm) of a semiconductor material like Bi_{0.5}Sb_{1.5}Te₃ or Bi₂Te₃. Thermoelement 504 is electrically and thermally coupled with a liquid metal electrode 506 that is a micron-sized droplet of liquid metal. All the metals used in the NEAT device structure explained in conjunction with FIG. 1 may be used in this embodiment also. Liquid metal electrode 506 is thermally and electrically coupled to a second metal plate 508. Second metal plate 508 acts as the contact surface with the object to be cooled. Second metal plate 508 is thermally insulated from first metal plate 502. The lateral dimension of the metal plates is in the range of 10-100 micrometers while the vertical dimension is in the range of 10-100 micrometers.

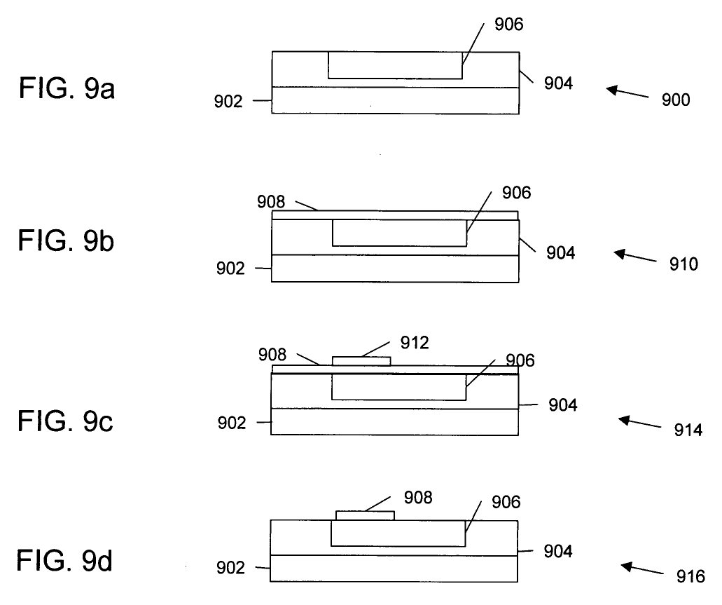

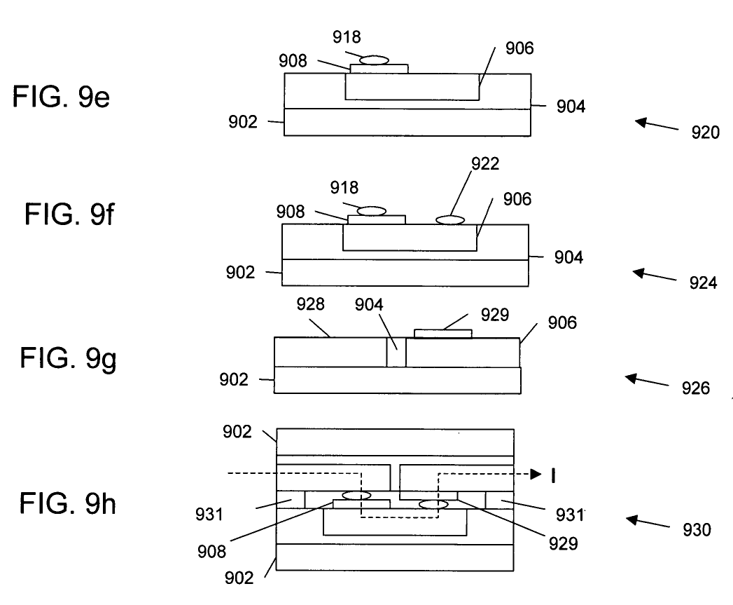

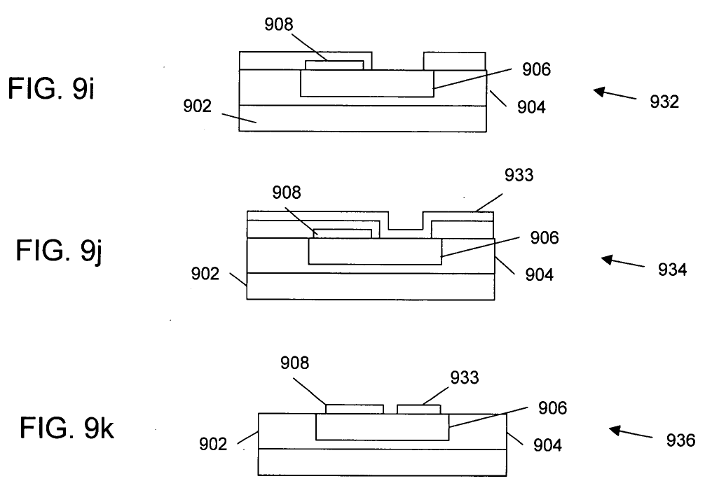

Dielectric material spacers 510 are placed between the metal plates for maintaining and controlling the spacing between the metal plates. The dielectric material spacers are made of a thermally insulating dielectric material. The spacers can be made in different forms, including thin film low-K dielectrics such as SiLK (SiLK resin is a solution of a low-molecular-weight aromatic thermosetting polymer) or aerogels, insulating epoxies and polystyrene beads. The surface tension of liquid metal allows for the use of various compatible forms of spacers and results in thermal stress-free NEAT devices. In an embodiment, the solid metal electrodes may be preplated with gold or indium based solders for easy integration of NEAT device structures in cooler configurations. Gold and Indium solder plating allows low temperature soldering of the NEAT devices in the conventional electrically-series and thermally-parallel cooler configurations as described in conjunction with FIGS. 7 and 8.

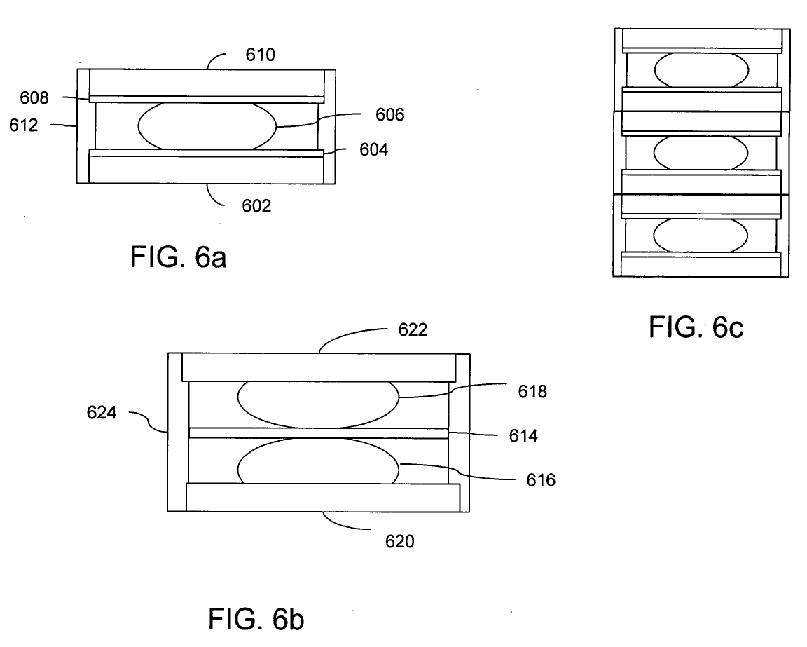

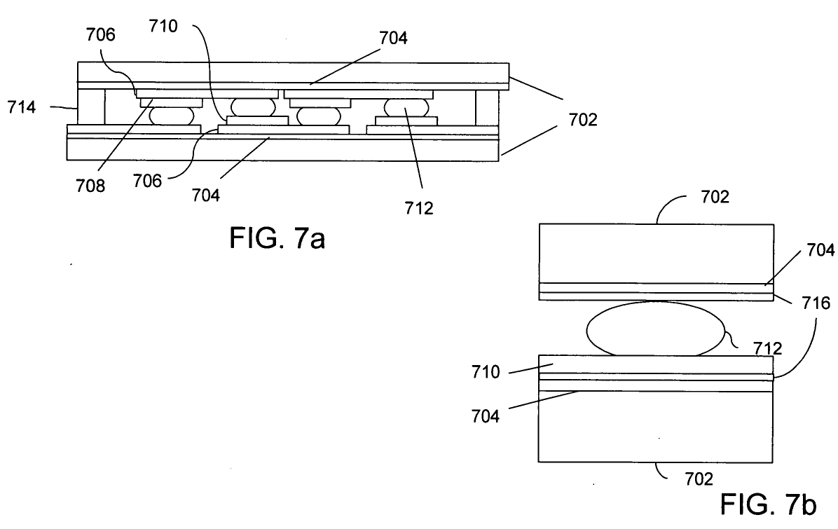

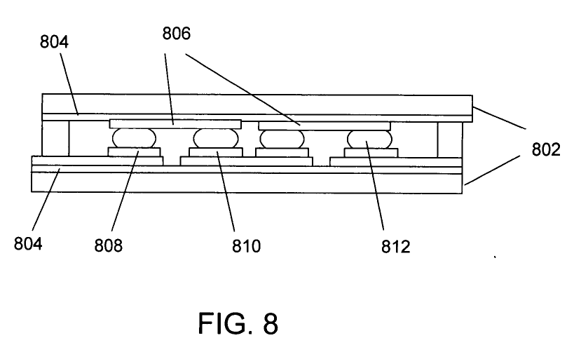

Referring primarily to FIG. 6a, another embodiment of the thermoelectric device in accordance with the present invention is described. This is a nonequilibrium symmetric thermoelectric (NEST) device, which is a modification of the NEAT device as described in conjunction with FIG. 5.

A first solid metal electrode 602 is thermally coupled to a first thermoelectric thin film 604. Thermoelectric thin film 604 is electrically and thermally coupled to a liquid metal electrode 606. Liquid metal electrode 606 is coupled to a second thermoelectric thin film 608, which is in turn electrically and thermally coupled to a second solid metal electrode 610. Spacing between the two solid metal electrodes 602 and 610 is maintained using a dielectric material 612 in a similar manner as the embodiment described in conjunction with FIG. 5.

Another embodiment of the thermoelectric device in accordance with the present invention is described in FIG. 6b. Thermoelectric thin film 614 is electrically and thermally coupled to two liquid metal electrodes 616 and 618. Thermoelectric thin film 614 may be supported at the ends using adhesives like epoxy resin. Liquid metal electrode 616 is electrically and thermally coupled to a first solid metal electrode 620 while the second liquid metal electrode 618 is electrically and thermally coupled to a second solid metal electrode 622. Spacing between the two solid metal electrodes 620 and 622 is maintained using a dielectric material 624 in a similar manner as the embodiments described in conjunction with FIG. 5 and FIG. 6a.

The embodiment described in FIG. 6b is more complex to fabricate than the other embodiments. However, the embodiment becomes structurally robust if one of the liquid electrodes is replaced by an alternate phonon conduction impeding medium such as solid Indium or Lead or Indium-Lead.

The NEAT or NEST devices as described in conjunction with FIGS. 5 and 6a can also be cascaded or connected in series to increase the temperature differentials across a unit element. FIG. 6c shows a cascaded NEST device comprising a stack of the devices of FIG. 6a. The temperature differentials achieved by individual units get added linearly to obtain the final temperature differential of the cascaded system. These macroscopic elements can then be assembled in electrically-series and thermally-parallel cooler configurations by processes well established in the conventional thermoelectric technology. More information about the electrically series and thermally parallel cooler structures and their fabrication can be found in Thermoelectrics: Basic Principles and New Materials Development by G. Nolas, J. Sharp, and H. Goldsmid, Springer-Verlag, Berlin Heidelberg, 2001. Alternatively, the abovementioned NEAT and NEST devices can be integrated into a thermoelectric cooler using a thin film process.

Referring to FIG. 7a, an embodiment of the cascaded NEAT device formed by merging two substrates of single (n-type or p-type) polarity thermoelements deposited on solid metal electrodes, is illustrated.

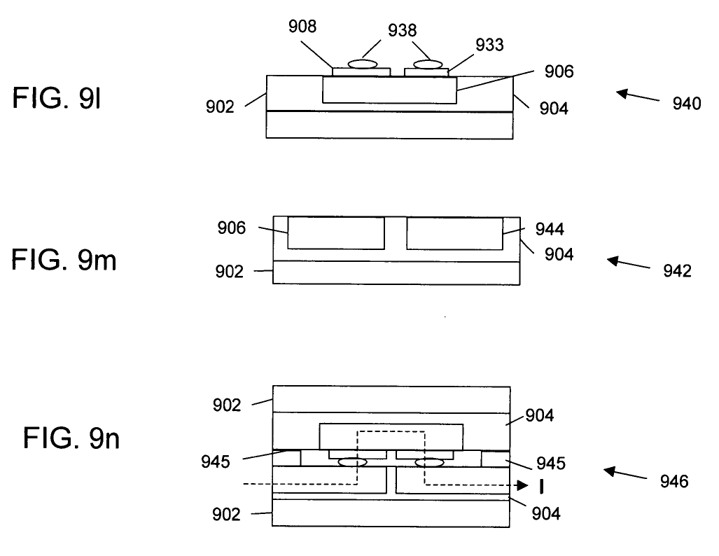

Silicon wafers 702 with thin films of silicon dioxide 704 deposited on them, act as substrates for forming the thermoelectric devices. Alternate substrates such as Gallium Arsenide wafers or Indium Phosphide wafers or thermally-conducting polished ceramic substrates or polished metal wafers can be used instead of the silicon wafers. Solid metal electrodes 706 are deposited over silicon dioxide film 704. Single polarity thermoelements (typically 10-100 nm thick) are alternately arranged on solid metal electrodes 706 so that they form an electrical series circuit. The alternate thermoelements are of opposite polarity. For e.g, a p-type thermoelement 708 and an n-type thermoelement 710 are arranged alternately to form an electrical series circuit. Electrodes of liquid metal 712 are coupled to the thermoelements. This embodiment can be seen as a number of NEAT devices (incorporating thermoelements of opposite polarity arranged alternately) combined together in series. The process of fabrication of such thermoelectric devices is explained in detail in conjunction with FIG. 9. The n and p NEAT devices form an electrically series and thermally parallel circuit, similar to thermoelectric modules using conventional thermoelements. The two substrates are spaced apart by dielectric standoffs 714 at the edges. Similar to the other embodiments, the compressibility of the liquid metal dots allows stress-free assembly.

FIG. 7b shows the enlarged cross section of a single NEAT device from the thermoelectric device described in conjunction with FIG. 7a. Multiple patterned metal electrodes 716 are deposited on ultra-thin (10-100 nm) silicon dioxide or silicon nitride dielectric. The ultra-thin silicon dioxide or silicon nitride dielectric 704 is required for electrical isolation of thermoelements in the series circuit, while minimizing the thermal resistance between each metal electrode 716 and each silicon substrate 702. Further each metal electrode is typically made of Nickel-plated Copper, or Aluminum. A Platinum layer is added at the thermoelectric boundary for preventing electromigration at high current densities and forming better metal-semiconductor contacts. In addition, ultra-thin (10-30 nm) layers of Titanium/Tungsten are added for better adhesion of Platinum to Aluminum and Copper to Silicon dioxide.

Referring to FIG. 8, another embodiment of a thermoelectric device in accordance with the present invention is described. The thermoelectric device in accordance with this embodiment has silicon wafers 802 with thin films of silicon dioxide 804 deposited on them, acting as substrates. Solid metal electrodes 806 are deposited over silicon dioxide film 804. Single polarity thermoelements are alternately arranged on solid metal electrodes 806 so that they form an electrically series circuit. The alternate thermoelements are of opposite polarity. For e.g, a p-type thermoelement 808 and an n-type thermoelement 810 are arranged alternately to form an electrically series circuit. Electrodes of liquid metal 812 are disposed between to the thermoelements. In this embodiment, alternate n-type and p-type thermoelements are arranged monolithically on the same side of liquid metal electrodes 812. This is in contrast with the embodiment of FIG. 7a where alternate n-type and p-type thermoelements are arranged on the opposite side of liquid metal electrodes 712.

The fabrication process for forming the abovementioned embodiments of the invention is hereinafter explained in detail. The diagrams illustrate the process sequence of fabricating one pair of cascaded NEAT devices. However, it will be obvious to those skilled in the art that the batch process described herewith can be generalized to fabrication of multiple pairs of cascaded NEAT devices (typical of practical thermoelectric coolers). FIG. 9a shows a base structure 900 having a silicon wafer 902 (with a thickness of 100-500 microns) used as a substrate. A blanket layer of silicon dioxide 904 (with a thickness of 0.5 micron) is deposited on the surface of wafer 902 by chemical vapor deposition (CVD) or plasma-enhanced CVD processes using tetra-ethyl-ortho-silicate (TEOS) or by direct thermal oxidation of silicon. The oxide is then patterned by conventional optical lithography techniques and etched by plasma etching techniques to form pits in oxide. Copper seed layers (TaN/Ta/Cu) are deposited in the pits by physical vapor deposition (PVD) techniques. Copper is then electrochemically plated onto the seed layers to cover up the pits. The surface is then polished by chemical and mechanical polishing (CMP) techniques. Thin blanket layers (<20 nm) of TiW and Pt is deposited by PVD and patterned over the copper links by plasma etching techniques. These metallization steps result in the composite metal structure 906. A 10-100 nm film of thermoelectric material 908 is then sputtered by PVD or metallorganic CVD techniques onto base structure 900. FIG. 9b shows resulting structure 910 after sputtering of thermoelectric film 908.

Structure 910 is then spin-coated with a layer of photoresist 912 that is developed and patterned by conventional lithography techniques. The coating of photoresist layer 912 is done in such a manner that the lateral dimensions of the photoresist layer is same as the desired lateral dimensions of the thermoelement. FIG. 9c shows resulting structure 914 after a layer of photoresist has been coated and patterned.

This is followed by etching of thermoelectric layer by plasma etching techniques or wet-etching using a combination of dilute hydrochloric acid and nitric acid. Next the photoresist is removed by dissolution in organic solvents that do not affect the thermoelectric layer 908. Resulting structure 916 formed after removal of exposed photoresist layer is shown in FIG. 9d.

Droplets of liquid metal 918 are then deposited on the thermoelectric layer 908 by micropipette dispensing techniques, or by pressure fill techniques or by jet printing or by sputtering methods. FIG. 9e shows the NEAT thermoelectric device structure 920 as described in conjunction with FIG. 1.

Hereinafter, the method for fabricating NEAT thermoelectric devices in accordance with the embodiments of FIGS. 7 and 8 has been described.

As described earlier, the embodiment of FIG. 7 combines two substrates of single (n-type or p-type) polarity thermoelements and arranges them alternately to form an electrically series and thermally parallel circuit.

To manufacture a NEAT device in accordance with FIG. 7, structure 920 is used and a second liquid metal droplet 922 is dispensed on composite metal layer 906, resulting in structure 924 as depicted in FIG. 9f.

Thereafter, a structure 926 (as shown in FIG. 9g) is formed using the method as described in conjunction with FIGS. 9a through 9d. Structure 926 is similar to structure 916 (of FIG. 9d) except that structure 926 comprises an additional composite metal layer 928. Structure 926 has a semiconductor thermoelement 929 that has a polarity opposite to that of thermoelement 908 in structure 924. Thus, in case the thermoelement of structure 924 is n-type, structure 926 will have a p-type thermoelement and vice-versa. The two structures 924 and 926 are then combined to form a structure 930, which is electrically in series and thermally in parallel. The structures can be combined by flip-chip backside-to-front aligners and held in place by polymer resin or epoxy seals on the periphery of the structure. Structure 930 has been illustrated in FIG. 9h. The structures 924 and 926 are separated using dielectric standoffs 931 at the edges. Thus, structure 930 combines complementary polarity thermoelements 908 and 929 to form an electrically series and thermally parallel circuit.

As described earlier, the embodiment of FIG. 8 combines two substrates, one with thermoelectric elements (both n-type or p-type) and the other with simple metal links and arranges them to form an electrically series and thermally series circuit.

To manufacture a NEAT device in accordance with FIG. 8, structure 916 is taken and a layer of photoresist is deposited and patterned all over the surface except the region where thermoelement of opposite polarity has to be deposited. Resulting structure 932 is shown in FIG. 9i. Thereafter, a thermoelectric film of opposite polarity is deposited by PVD or metallorganic CVD techniques over the surface of structure 932 resulting in structure 934. FIG. 9j shows structure 934.

The photoresist film is then lifted off by dissolution in organic solvents to leave behind structure 936 as illustrated in FIG. 9k. As shown, FIG. 9k has opposite polarity thermoelements 908 and 933 deposited on it. Liquid metal drops 938 are dispensed on the thermoelements 908 and 933 by micropipette or pressure injection techniques resulting in structure 940 as illustrated in FIG. 9l.

Thereafter, a structure 942 (as shown in FIG. 9m) is formed using the method as described in conjunction with FIG. 9a. Structure 942 is similar to basic structure 900 (of FIG. 9a) except that structure 942 comprises an additional metal electrode 944. The two structures 940 and 942 are then combined by flip-chip backside-to-front aligners and held in place by polymer resin or epoxy seals on the periphery of the structure to form a structure 946, which is electrically in series and thermally in parallel. Structure 946 has been illustrated in FIG. 9n. The structures 940 and 942 are separated using dielectric standoffs 945 at the edges. As shown, structure 946 combines two substrates, one with thermoelectric elements (both n-type or p-type) and the other with simple metal links and arranges them to form an electrically series and thermally series circuit. In structure 946 alternate n-type and p-type thermoelements 908 and 933 are arranged monolithically on the same side of liquid metal droplets 938.

The thermal and electrical operation of the embodiments shown in FIG. 7a and FIG. 8 are identical. The main advantage of the embodiment of FIG. 7 is that the fabrication and processing conditions of p-type thermoelement substrate can be very different than that of the n-type substrate. This flexibility allows very different types of n-type and p-type thermoelectric materials to be integrated in the cooler. The main advantage of the embodiment of FIG. 8 is that only one of the substrate undergoes complex processing steps of deposition of thermoelectric materials. The other substrate without the thermoelements has simple metal links, and can be implemented on the backside of an external device. The external device could be a silicon-based microprocessor or an gallium arsenide optoelectronic chip or the cold plate of a refrigerator.

The cascaded NEST structures can be fabricated by a method same as that used to manufacture cascaded NEAT structure shown in FIG. 8 (where alternate n-type and p-type thermoelements are arranged on the same side of liquid metal electrodes).

### Advantages and Applications

The present invention uses ultra-thin thermoelectric layers to form the thermoelements. As growing thin thermoelectric films is much easier than growing thick thermoelectric films, the thermoelectric devices in accordance with the present invention provide an inherent advantage in manufacturing process.

Although the present invention has been described primarily with reference to a thermoelectric cooling device, it will be apparent to one skilled in the art that the invention can very well be used as a power generator for generation of electricity. It will be apparent that when used in the peltier mode (as described above) the thermoelectric cooling device is used for refrigeration while in the Seebeck mode the device may be used for electrical power generation. More information about electrical power generation may be found in CRC Handbook of Thermoelectrics, edited by D. M. Rowe, Ph.D., D. Sc., CRC Press, New York, (1995) pp. 479-488 and in Advanced Engineering Thermodynamics, 2^{nd} Edition by Adiran Bejan, John Wiley & Sons, Inc., New York (1997) pp. 675-682, both of which are hereby incorporated herein for all practical purposes.

While the preferred embodiments of the invention have been illustrated and described, it will be clear that the invention is not limited to these embodiments only. Numerous modifications, changes, variations, substitutions and equivalents will be apparent to those skilled in the art without departing from the spirit and scope of the invention as described in the claims.

1. A thermoelectric structure comprising:
a. a solid metal electrode;
b. a thermoelement thermally coupled to the solid metal electrode; and
c. a phonon conduction impeding medium the phonon conduction impeding medium being coupled with the thermoelement, the phonon conduction impeding medium being thermally insulated from the solid metal electrode.

2. The thermoelectric structure in accordance with claim 1 wherein the phonon conduction impeding medium is a liquid metal.

3. The thermoelectric structure in accordance with claim 1 wherein the phonon conduction impeding medium is selected from the group consisting of: gallium, indium, gallium-indium, lead, lead-indium, cesium doped gallium-indium, gallium-indium-copper, gallium-indium-tin and mercury.

4. The thermoelectric structure in accordance with claim 1 wherein the thermoelement is selected from the group consisting of: p-type Bi—Sb—Te, n-type Bi—Te compounds, superlattices of Bi₂Te₃ and Sb₂Te₃, Bismuth chalcogenides, Lead chalcogenides, complex chalcogenide compounds of Zn, Bi, TI, In, Ge, Hf, K, and Cs, SiGe compounds, BiSb compounds and skutteridites compounds of Co, Sb, Ni, and Fe.

5. A thermoelectric device comprising:
a. a first solid metal electrode;
b. a thermoelement thermally coupled to the first solid metal electrode;
c. a phonon conduction impeding medium, the phonon conduction impeding medium being coupled with the thermoelement, the phonon conduction impeding medium being thermally insulated from the first solid metal electrode; and
d. a second solid metal electrode thermally coupled to the phonon conduction impeding medium.

6. The thermoelectric device in accordance with claim 5 wherein the phonon conduction impeding medium is a liquid metal.

7. The thermoelectric device in accordance with claim 5 further comprising a dielectric material, the dielectric material maintaining spacing between the first solid metal electrode and the second solid metal electrode.

8. The thermoelectric device in accordance with claim 5 wherein multiple thermoelectric devices are connected electrically in series and thermally in parallel.

9. The thermoelectric device in accordance with claim 6 further including a power source coupled to the thermoelectric device such that the thermoelectric device operates as a thermoelectric cooler.

10. The thermoelectric device in accordance with claim 6 wherein a temperature gradient is maintained between the solid metal electrodes such that the thermoelectric device operates as a thermoelectric power generator.

11. The thermoelectric device in accordance with claim 6 wherein the first and second solid metal electrodes comprise a multi-layered plate of different metals.

12. The thermoelectric device in accordance with claim 11 wherein the multi-layered metal plate is made of Nickel-plated Copper or Aluminum coated with layers of platinum and TiW.

13. The thermoelectric device in accordance with claim 5 wherein the phonon conduction impeding medium is selected from the group consisting of: gallium, indium, gallium-indium, lead, lead-indium, cesium doped gallium-indium, gallium-indium-copper, gallium-indium-tin and mercury.

14. The thermoelectric device in accordance with claim 5 wherein the thermoelement is selected from the group consisting of: p-type Bi—Sb—Te, n-type Bi—Te compounds, superlattices of Bi₂Te₃ and Sb₂Te₃, Bismuth chalcogenides, Lead chalcogenides, complex chalcogenide compounds of Zn, Bi, TI, In, Ge, Hf, K, and Cs, SiGe compounds, BiSb compounds and skutteridites compounds of Co, Sb, Ni, and Fe.

15. A thermoelectric device comprising:
a. a first solid metal electrode;
b. a first thermoelement thermally coupled to the first solid metal electrode;
c. a phonon conduction impeding medium, the phonon conduction impeding medium being coupled with the first thermoelement, the phonon conduction impeding medium being thermally insulated from the first solid metal electrode;
d. a second thermoelement, the second thermoelement being connected to the phonon conduction impeding medium;
e. a second solid metal electrode thermally coupled to the second thermoelement, the second solid metal electrode being thermally insulated from the phonon conduction impeding medium; and
f. a dielectric material, the dielectric material maintaining spacing between the first solid metal electrode and the second solid metal electrode.

16. The thermoelectric device in accordance with claim 15 wherein multiple thermoelectric devices are connected electrically in series and thermally in parallel.

17. The thermoelectric structure in accordance with claim 15 wherein the phonon conduction impeding medium is a liquid metal.

18. A thermoelectric device comprising:
a. a first solid metal electrode;
b. a second solid metal electrode;
c. a first phonon conduction impeding medium, the first phonon conduction impeding medium being coupled with the first solid metal electrode;
d. a second phonon conduction impeding medium, the second phonon conduction impeding medium being coupled with the second solid metal electrode;
e. a thermoelement thermally coupled to the first and second phonon conduction impeding mediums; and
f. a dielectric material, the dielectric material maintaining spacing between the first solid metal electrode and the second solid metal electrode.

19. A method for fabricating a thermoelectric device, the method comprising the steps of:
a. forming a first base structure, the first base structure comprising a silicon dioxide coated silicon wafer and a first solid metal electrode;
b. disposing a first thermoelement on the base structure;
c. disposing a first phonon conduction impeding medium on the first thermoelement;
d. disposing a second phonon conduction impeding medium on the first metal electrode;
e. forming a second base structure, the second base structure comprising a silicon dioxide coated silicon wafer, a second metal electrode, a third metal electrode and a second thermoelement, the polarity of the second thermoelement being opposite to the polarity of the first thermoelement; and
f. combining the second base structure with the structure resulting after executing step d, the combination resulting in the formation of the thermoelectric device.

20. The method for fabricating a thermoelectric device in accordance with claim 19 wherein the step of forming a first base structure further comprises:
a. depositing a silicon dioxide layer on the surface of a silicon wafer; and
b. depositing a composite solid metal electrode structure over the silicon dioxide layer.

21. The method for fabricating a thermoelectric device in accordance with claim 20 wherein the step of depositing a silicon dioxide layer is performed using a technique selected from the group of chemical vapor deposition, plasma enhanced chemical vapor deposition and direct thermal oxidation of silicon wafer.

22. The method for fabricating a thermoelectric device in accordance with claim 20 wherein the step of depositing a composite solid metal electrode structure comprises the steps of:
a. patterning the silicon dioxide layer;
b. etching the patterned silicon dioxide layer to form pits in the silicon dioxide layer;
c. depositing a copper seed layer in the pits;
d. plating copper onto the seed layers to cover up the pits;
e. polishing the surface of the plated copper; and
f. depositing and patterning TiW and platinum layers over the plated copper.

23. The method for fabricating a thermoelectric device in accordance with claim 22 wherein the steps of depositing copper seed layers and depositing TiW and platinum layers are performed by physical vapor deposition.

24. The method for fabricating a thermoelectric device in accordance with claim 22 wherein the step of etching the patterned silicon dioxide layer is performed by plasma etching techniques.

25. The method for fabricating a thermoelectric device in accordance with claim 22 wherein the step of polishing the surface of the plated copper is performed by chemical and mechanical polishing techniques.

26. The method for fabricating a thermoelectric device in accordance with claim 19 wherein the step of disposing a first thermoelement comprises the sub steps of:
a. sputtering a film of thermoelectric material onto the base structure;
b. coating a photoresist layer with lateral dimensions equal to the dimensions of first thermoelement;
c. etching the photoresist layer using techniques selected from plasma etching and wet etching; and
d. removing the photoresist by dissolving in organic solvents.

27. The method for fabricating a thermoelectric device in accordance with claim 19, wherein the steps of disposing first and second phonon conduction impeding mediums are performed by at least one technique selected from a group consisting of micropipette dispensing techniques, pressure fill techniques and jet printing techniques.

28. The method for fabricating a thermoelectric device in accordance with claim 19, wherein the step of combining is performed by flip-chip backside-to-front aligners.

29. A method for fabricating a thermoelectric device, the method comprising the steps of:
a. forming a first base structure, the first base structure comprising a silicon dioxide coated silicon wafer and a first solid metal electrode;
b. adding a first thermoelement on the base structure;
c. depositing and patterning a layer of photoresist over a preselected area of the first base structure;
d. depositing a layer of a second thermoelement over the structure formed after step c, the polarity of the second thermoelement being opposite to the polarity of the first thermoelement;
e. removing the layer of photoresist by dissolving in organic solvents to form a second base structure;
f. forming a third base structure by adding a first phonon conduction impeding medium over the first thermoelement and a second phonon conduction impeding medium over the second thermoelement of the second base structure; and
g. combining the third base structure with the second base structure, the combination resulting in the formation of the thermoelectric device.
